(19) United States
(12) Patent Application Publication
(10) Pub. No.: US 2025/0133785 A1
(43) Pub. Date: Apr. 24, 2025

(54) STACKED NANOSHEET GATE-ALL-AROUND DEVICE WITH AIR SPACER AND METHOD OF MANUFACTURING STACKED NANOSHEET GATE-ALL-AROUND DEVICE WITH AIR SPACER

(71) Applicant: Institute of Microelectronics, Chinese Academy of Sciences, Beijing (CN)

(72) Inventors: Qingzhu ZHANG, Beijing (CN); Lianlian LI, Beijing (CN); Anyan DU, Beijing (CN); Huaxiang YIN, Beijing (CN); Lei CAO, Beijing (CN); Jiaxin YAO, Beijing (CN); Zhaohao ZHANG, Beijing (CN); Qingkun LI, Beijing (CN); Guanqiao SANG, Beijing (CN)

(21) Appl. No.: 18/907,334

(22) Filed: Oct. 4, 2024

(30) Foreign Application Priority Data
Oct. 20, 2023 (CN) 202311363144.9

(51) Int. Cl. H01L 29/06; H01L 29/10; H01L 29/423; H01L 29/66; H01L 29/775; H01L 29/786

(52) U.S. Cl. CPC H10D 62/116; H10D 30/014; H10D 62/364; H10D 64/015; H10D 30/43; H10D 30/6735; H10D 30/6757; H10D 62/121

(57) ABSTRACT

The present disclosure provides a stacked nanosheet gate-all-around device with an air spacer and a manufacturing method. The device includes: a substrate, where a first dielectric layer is on the substrate, a gap array is in the first dielectric layer, the gap array includes multiple gap units, and each gap unit is in a fin shape above the substrate; a nanosheet stacking portion above the gap unit, including a stack formed by multiple nanosheets, and the stack formed by the nanosheets constitutes multiple conductive channels; a gate-all-around surrounding the nanosheet stacking portion; and a source/drain region on two opposite sides of the nanosheet stacking portion, where an empty spacer is between the source/drain region and the gate-all-around. An interior of the gap array and an interior of the empty spacer are filled with at least one of air, a reducing gas, or an inert gas.

### CROSS REFERENCE TO RELATED APPLICATION

This application claims priority to Chinese Patent Application No. 202311363144.9, filed on Oct. 20, 2023, the entire content of which is incorporated herein in its entirety by reference.

### TECHNICAL FIELD

The present disclosure relates to a field of transistors, and in particular to a stacked nanosheet gate-all-around device with an air spacer and a method of manufacturing a stacked nanosheet gate-all-around device with an air spacer.

### BACKGROUND

With the continuous miniaturization of feature sizes of transistors, the conventional CMOS device undergoes a transition from a planar structure to a three-dimensional structure, which improves the device performance while reducing the impact of the short channel effect. At present, the mainstream three-dimensional structure transistor is FinFET. In the latest International Roadmap for Devices and Systems (IRDS), Nanosheet Gate-all-around Transistor (Nanosheet-GAAFET) is a key device that may effectively replace FinFET after a 3 nm node, which may significantly suppress the short channel effect and improve the current driving performance of the device. At present, the research progress of Nanosheet-GAAFET has received widespread attention from both academia and industry.

The preparation process of the stacked Nanosheet-GAAFET is compatible with the preparation process of the mainstream FinFET. Compared with the traditional FinFET device, a parasitic capacitance of the stacked Nanosheet-GAAFET device increases sharply due to the greatly increased area from the gate to the source/drain and from the gate to the sub-fin, which will significantly reduce an operating speed of a circuit. Therefore, it is desired to use a material with a low dielectric constant as a spacer to reduce the parasitic capacitance, and air is considered the most ideal low-k material. In the FinFET device, the air gap is proved to be capable of effectively reducing the impact of parasitic capacitance, but a series of problems such as the process is unstable, the structure is difficult to control accurately and the like exist.

### SUMMARY

A first aspect of the present disclosure provides a stacked nanosheet gate-all-around device with an air spacer, including:
a substrate, where a first dielectric layer is provided on the substrate, a gap array is provided in the first dielectric layer, the gap array includes a plurality of gap units, and each gap unit is in a fin shape above the substrate;
a nanosheet stacking portion provided above the gap unit, where the nanosheet stacking portion includes a stack formed by a plurality of nanosheets, and the stack formed by the nanosheets constitutes a plurality of conductive channels;
a gate-all-around surrounding the nanosheet stacking portion; and
a source/drain region located on two opposite sides of the nanosheet stacking portion, where an empty spacer is provided between the source/drain region and the gate-all-around,
where an interior of the gap array and an interior of the empty spacer are filled with at least one of air, a reducing gas, or an inert gas.

Furthermore, the stacked nanosheet gate-all-around device with the air spacer further includes a second dielectric layer covering the gate-all-around,
where the gate-all-around includes an interlayer gate filled among the plurality of nanosheets and a peripheral gate surrounding the nanosheet stacking portion, and
where the empty spacer includes a first empty spacer located between the second dielectric layer and the peripheral gate, and a second empty spacer located between the interlayer gate and the source/drain region.

Furthermore, the substrate further has a cavity structure located below the gap unit.

Furthermore, a width of the nanosheet is in a range of 5 nm to 50 nm, and a thickness of the nanosheet is in a range of 3 nm to 20 nm.

Furthermore, a width of the cavity structure is in a range of 100 nm to 10 μm.

Furthermore, the gate-all-around includes a gate dielectric layer and a metal gate layer, and the gate dielectric layer is only located between the metal gate layer and the nanosheet.

A second aspect of the present disclosure provides a method of manufacturing a stacked nanosheet gate-all-around device with an air spacer, which may be used to manufacture the device in the first aspect. The method includes:
providing a support substrate;
forming a sacrificial layer on the support substrate;
forming a first semiconductor layer on an upper surface of the sacrificial layer;
epitaxially growing a superlattice stack on a surface of the first semiconductor layer, where the superlattice stack is composed of different semiconductor materials alternatively stacked;
etching the superlattice stack and a partial thickness of the first semiconductor layer to form a fin;
forming a first dielectric layer on the first semiconductor layer as a shallow trench isolation, where an upper surface of the first dielectric layer is not higher than a bottom of the superlattice stack;
depositing a dummy gate on the fin and forming a first spacer on a sidewall of the dummy gate;
etching the superlattice stack in the fin to release a source/drain area;
forming a second spacer on a sidewall of the superlattice stack in the fin;
depositing a doped semiconductor material in the source/drain area to form a source/drain region;
forming a second dielectric layer on the source/drain region, where the second dielectric layer is flush with the dummy gate;
removing the dummy gate;
etching off a part of the semiconductor materials in the superlattice stack to release a nanosheet channel, where a stack formed by the nanosheets constitutes a plurality of conductive channels;
forming a gate-all-around to surround the stack formed by the nanosheets;
etching the support substrate from a bottom of the support substrate and stopping the etching at the sacrificial layer, so as to form a first cavity structure;
selectively etching the sacrificial layer and the first semiconductor layer from the first cavity structure, and stopping the selectively etching at the formed gate-all-around, so as to form a second cavity structure and a gap array inside the first semiconductor layer; and
etching and removing the first spacer and the second spacer to form a first empty spacer and a second empty spacer, respectively.

Furthermore, the forming a gate-all-around includes: forming a gate dielectric layer, and then forming a metal gate layer by stacking;
where after etching and removing the first spacer and the second spacer, the method further includes: removing the gate dielectric layer adjacent to the gap array, and removing the gate dielectric layer on a sidewall of the first empty spacer and a sidewall of the second empty spacer;
after etching and removing the first spacer and the second spacer, the method further includes:
   removing the remaining sacrificial layer and the support substrate.

Furthermore, the method further includes: replacing a gas in the first empty spacer, the second empty spacer, the second cavity structure, and the gap array with at least one of air, a reducing gas, or an inert gas.

Furthermore, the first semiconductor layer is made of silicon, and the sacrificial layer is made of silicon germanium.

Furthermore, the first spacer and the second spacer are made of silicon nitride, and the first spacer and the second spacer are etched by using a phosphoric acid solution.

### BRIEF DESCRIPTION OF THE DRAWINGS

Various other advantages and benefits will become clear to those ordinary skilled in the art by reading the detailed description of the preferred embodiments below. The drawings are only for the purpose of illustrating the preferred embodiments, and are not considered as limitation of the present disclosure.

FIGS. 1-21 show schematic diagrams of structures obtained at various steps in a method of manufacturing a stacked nanosheet gate-all-around device provided by the present disclosure;

FIG. 22 shows a cross-sectional view of a stacked nanosheet gate-all-around device provided by the present disclosure in Y-Y′ direction; and

FIG. 23 shows a cross-sectional view of a stacked nanosheet gate-all-around device provided by the present disclosure in X-X′ direction.

The X-X′ and Y-Y′ directions in the above figures are referenced to the directions indicated in FIG. 3.

### DETAILED DESCRIPTION OF EMBODIMENTS

Hereinafter, embodiments of the present disclosure will be described with reference to the drawings. However, it should be understood that these descriptions are only exemplary and are not intended to limit the scope of the present disclosure. In addition, in the following illustration, descriptions of well-known structures and technologies are omitted to avoid unnecessarily confusing the concepts of the present disclosure.

Various structural schematic diagrams according to the embodiments of the present disclosure are shown in the drawings. These drawings are not drawn to scale, in which some details are enlarged and some details may be omitted for the purpose of clear expression. The shapes, the relative sizes and the positional relationships of various regions and layers shown in the drawings are only exemplary, and may actually be deviated due to manufacturing tolerances or technical limitations. Moreover, those skilled in the art may additionally design regions/layers with different shapes, sizes and relative positions according to actual needs.

In the context of the present disclosure, when a layer/element is described to be “on” a further layer/element, the layer/element may be directly on the further layer/element, or there may be an intermediate layer/element therebetween. In addition, if a layer/element is “on” a further layer/element in one orientation, the layer/element may be “below” the further layer/element when the orientation is reversed.

The main objective of the present disclosure is to provide a stacked nanosheet gate-all-around device with an air spacer and a method of manufacturing a stacked nanosheet gate-all-around device with an air spacer. In the present disclosure, an air spacer is introduced in the Nanosheet-GAAFET as a spacer between a source/drain region and a gate, so that the parasitic capacitance of the device is greatly reduced, the process is stable, and the structure may be accurately controlled.

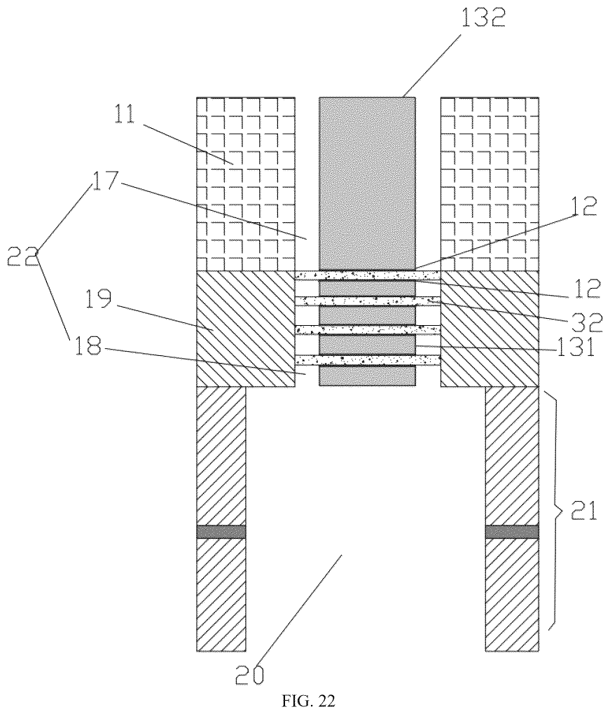

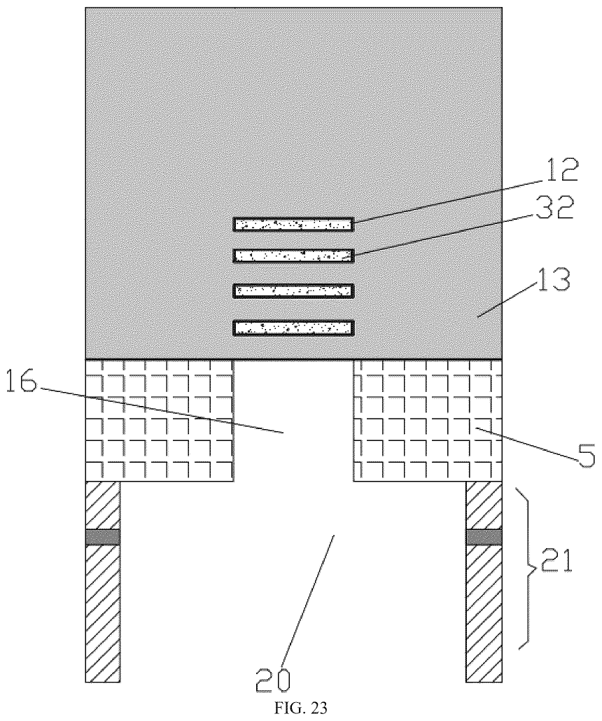

The present disclosure provides a Nanosheet-GAAFET with an all-air spacer structure as shown in FIGS. 22 and 23.

The Nanosheet-GAAFET with the all-air spacer structure provided in the present disclosure includes:
a substrate 21, where a first dielectric layer 5 is provided on the substrate 21, a gap array is provided in the first dielectric layer 5, the gap array includes a plurality of gap units 16, and each gap unit 16 is in a fin shape above the substrate 21;
a nanosheet stacking portion provided above the gap unit 16, where the nanosheet stacking portion includes a stack formed by a plurality of nanosheets (the silicon germanium layer 32 shown in the figure), and the stack formed by the nanosheets constitutes a plurality of conductive channels;
a gate-all-around surrounding the nanosheet stacking portion; and
a source/drain region 19 located on two opposite sides of the nanosheet stacking portion, where an empty spacer 22 is provided between the source/drain region 19 and the gate-all-around.

Therefore, in the present disclosure, a gas medium such as air is used as the isolation material (the gap unit and the empty spacer are filled with the gas) at a plurality of positions, including providing a gap array on the substrate and providing an empty spacer between the source/drain region and the gate-all-around, thereby significantly reducing the parasitic capacitance of the device and effectively improving the operating speed of the device and the circuit.

The gap unit 16 and the nanosheet stacking portion are in one-to-one correspondence, that is, one set of nanosheet stacking portions is located above one gap unit 16. Here, “one set of nanosheet stacking portions” refers to one fin, i.e., one vertically stacked unit. The gap unit 16 and the empty spacer 22 are both cavity structures, and the gas filled inside may be naturally circulating air during the preparation process, or a reducing gas or an inert gas after replacing the air, including but not limited to hydrogen, nitrogen, argon, and the like.

The Nanosheet-GAAFET of the present disclosure may be an NMOS, a PMOS, or a mixed arrangement of NMOS and PMOS. The doping type of the source/drain region of the transistor is matched with the type of the transistor.

The substrate 21 may be any substrate known to those skilled in the art for carrying elements of a semiconductor integrated circuit, such as silicon-on-insulator (SOI), bulk silicon, silicon carbide, germanium, silicon germanium, gallium arsenide or germanium-on-insulator. A corresponding top layer semiconductor material is silicon, germanium, silicon germanium, or gallium arsenide. The substrate may also be a stacked structure composed of a plurality of layers of semiconductor materials, such as a stack of silicon layer-silicon germanium layer-silicon layer.

The first dielectric layer 5 may be made of a high-k dielectric material such as oxide and oxynitride, e.g., typical silicon oxide (SiO₂), silicon oxynitride, silicon nitride (SiNₓ), and the like.

The nanosheet may be made of a semiconductor material such as silicon, silicon germanium, and the like. The source/drain region 19 may be made of a P-type or N-type doped semiconductor material, and the semiconductor materials used for the two may be the same or different.

For the convenience of encapsulating and protecting the circuit structure, a second dielectric layer 11 may be further provided to cover the gate-all-around. The second dielectric layer 11 may be made of a high-k dielectric material such as oxide and oxynitride, e.g., typical silicon oxide (SiO₂), silicon oxynitride, silicon nitride (SiNₓ), and the like.

Meanwhile, the gate-all-around may include an interlayer gate 131 filled among the plurality of nanosheets and a peripheral gate 132 surrounding the nanosheet stacking portion.

According to different gate distribution positions and structures, the empty spacer 22 includes a first empty spacer 17 located between the second dielectric layer and the peripheral gate, and a second empty spacer 18 located between the interlayer gate and the source/drain region.

The first empty spacer 17 and the second empty spacer 18 are both filled with air or other gases as an isolation material.

In some embodiments, the substrate 21 further has a cavity structure 20 located below the gap unit 16.

The nanosheet in the above-mentioned stacked nanosheet gate-all-around device may have a width in a range of 5 nm to 50 nm and a thickness in a range of 3 nm to 20 nm, which has a high integration.

The width of the cavity structure 20 may be in a range of 100 nm to 10 μm, which may match the size of the above-mentioned nanosheet.

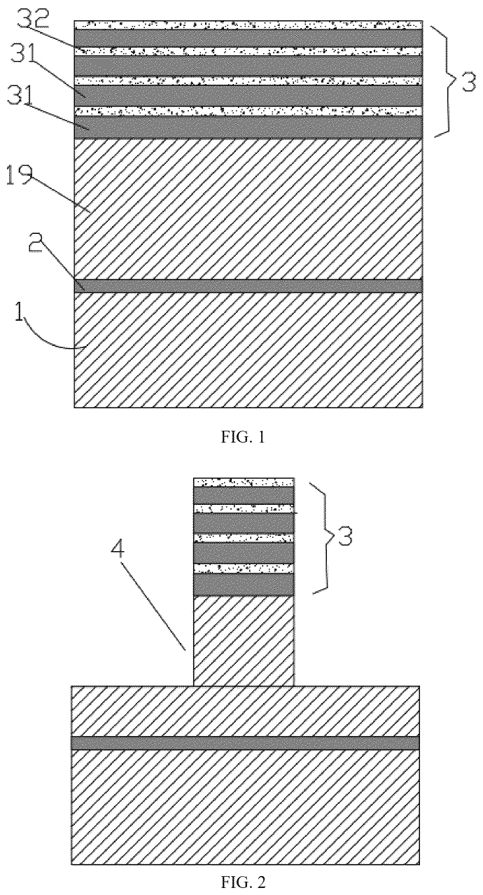

In some embodiments, the gate-all-around includes a gate dielectric layer 12 and a metal gate layer 13, and the gate dielectric layer 12 is only located between the metal gate layer 13 and the nanosheet. In this structure, no gate dielectric layer is provided on the sidewall of the gap unit 16 and the sidewall of the empty spacer 22, which may further reduce the parasitic capacitance. There are many methods of manufacturing the stacked nanosheet gate-all-around device described above. The present disclosure provides a manufacturing method in which the process is stable and the air spacer has excellent shape retention. The specific process is described below in conjunction with FIGS. 1-23.

In Step S1, a support substrate is provided; and a sacrificial layer 2 is formed on the support substrate 1 using a method such as PECVD, ALCVD, epitaxial growth, and the like. The sacrificial layer 2 may be made of a material that is similar to but different from the material of the support substrate 1 and the material of the subsequently formed first semiconductor layer, so that on the one hand, the sacrificial layer may play a role in buffering to improve the quality of the first semiconductor layer deposited subsequently, and on the other hand, the sacrificial layer may have an etching selectivity different from the support substrate and the first semiconductor layer 19 to achieve selective etching. In addition, since there is also an air gap inside the substrate in the present disclosure, no matter whether the transistor is NMOS or PMOS, the support substrate 1 may not be N-type or P-type doped, i.e., the step of doping the parasitic channel may be omitted. In addition, the support substrate 1 may be any substrate known to those skilled in the art for carrying elements of a semiconductor integrated circuit, such as silicon-on-insulator (SOI), bulk silicon, silicon carbide, germanium, silicon germanium, gallium arsenide or germanium-on-insulator. A corresponding top layer semiconductor material is silicon, germanium, silicon germanium, or gallium arsenide.

In Step S2, the first semiconductor layer 19 is formed on an upper surface of the sacrificial layer 2. The first semiconductor layer 19 serves as a parasitic channel in the final device structure, and similarly, the doping step may be omitted. The first semiconductor layer 19 may be made of silicon or other materials, which may be the same as or different from the material of the support substrate. The first semiconductor layer 19 may be formed using a method such as PECVD, ALCVD, epitaxial growth, and the like.

In Step S3, a superlattice stack 3, in which different semiconductor materials are alternately stacked, is epitaxially grown on a surface of the first semiconductor layer 19, so as to obtain the structure shown in FIG. 1. The superlattice stack 3 may be an alternating stack of a silicon layer 31 and a silicon germanium layer 32, or other combinations.

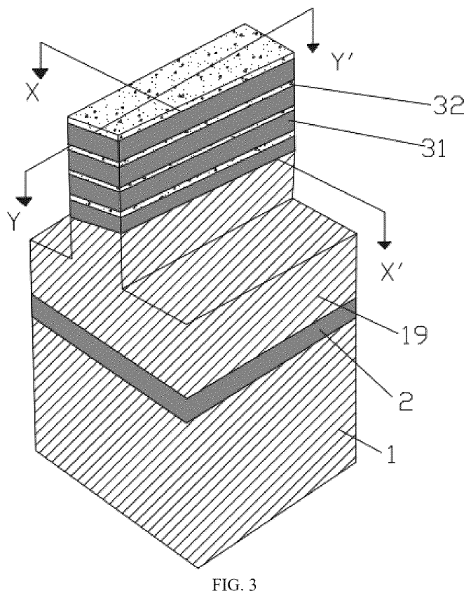

In Step S4, the superlattice stack 3 and a partial thickness of the first semiconductor layer 19 are etched to form a fin 4, so as to obtain the structure shown in FIG. 2. FIG. 3 shows a three-dimensional view of the structure, and FIG. 2 shows a sectional view of FIG. 3 in the X-X′ direction. During etching, a functional layer such as a hard mask, a barrier layer and the like may be used to obtain a predetermined pattern. The partial thickness refers to that the etching is performed into the first semiconductor layer 19 but does not penetrate the first semiconductor layer 19. In this way, the first semiconductor layer 19 will also form a convex structure that is conformal with the nanosheet. Etching may be dry etching or wet etching, or combined with CMP, or the like.

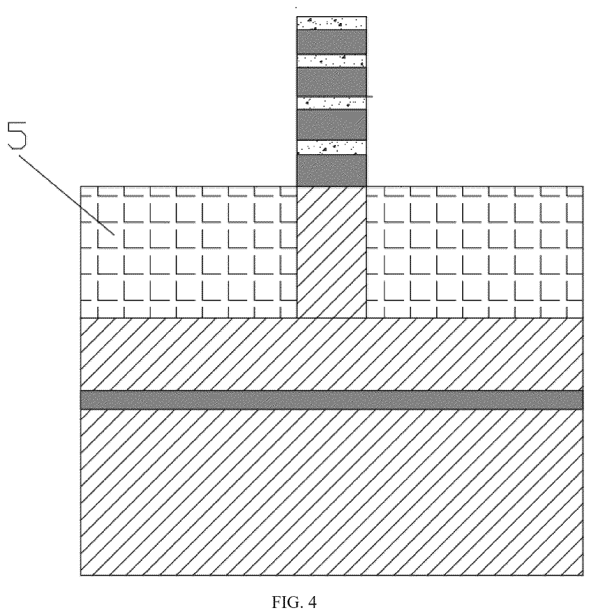

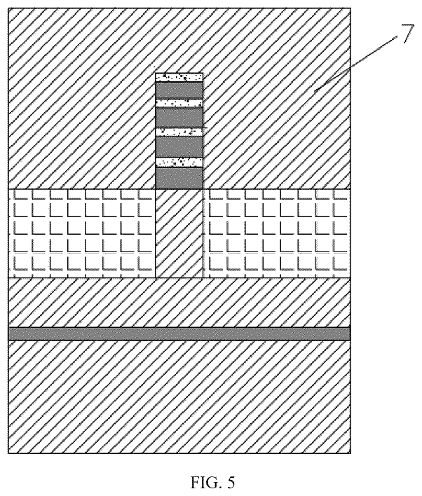

In Step S5, a first dielectric layer 5 is formed on the first semiconductor layer 19 as a shallow trench isolation, and an upper surface of the first dielectric layer 5 is not higher than the bottom of the superlattice stack 3, as shown in FIG. 4. The shallow trench isolation is not higher than the bottom of the superlattice stack 3, so that the subsequently deposited gate may completely surround the nanosheet.

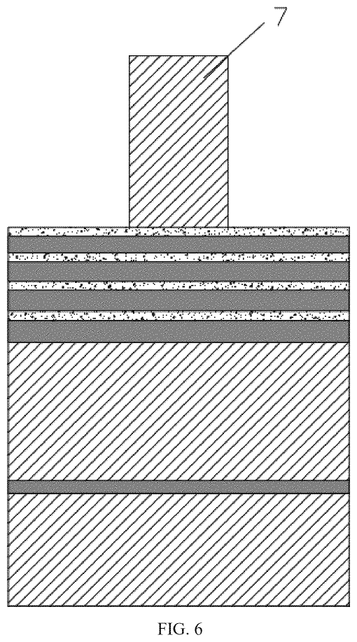

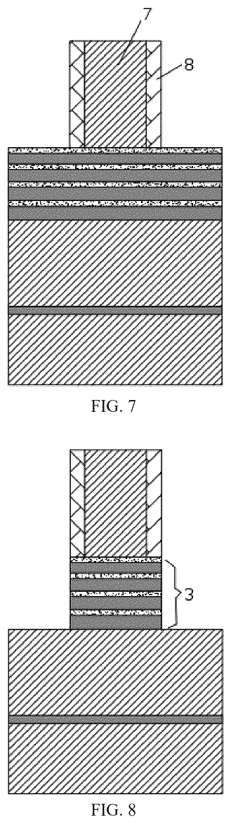

In Step S6, a dummy gate 7 is deposited on the fin 4, as shown in FIGS. 5 and 6 (FIG. 5 shows a cross-sectional view in the X-X′ direction, and FIG. 6 shows a cross-sectional view in the Y-Y′ direction); and a first spacer 8 is deposited on a sidewall of the dummy gate 7, as shown in FIG. 7 (a cross-sectional view in the Y-Y′ direction). The dummy gate 7 may be made of polycrystalline silicon or amorphous silicon. The first spacer 8 may be made of a material having a high etching selectivity relative to the superlattice stack, such as silicon nitride. The deposition method includes but is not limited to PECVD, ALCVD, and the like.

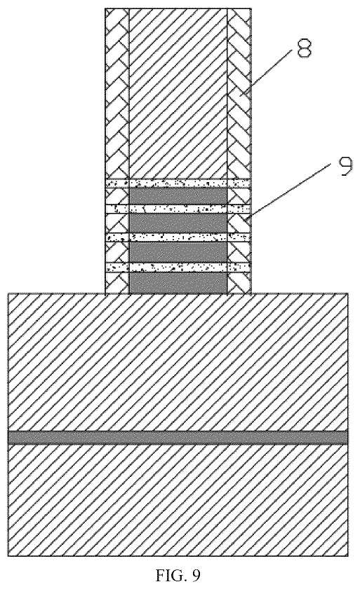

In Step S7, the superlattice stack 3 in the fin 4 is etched to release a source/drain area, as shown in FIG. 8 (a cross-sectional view in the Y-Y′ direction).

In Step S8, a second spacer 9 is formed on a sidewall of the superlattice stack 3 in the fin, as shown in FIG. 9 (a cross-sectional view in the Y-Y′ direction). The second spacer 9 may be made of a material having a high etching selectivity relative to the superlattice stack, such as silicon nitride, preferably the same material as the first spacer 8, so that the first spacer 8 and the second spacer 9 may be etched and removed simultaneously. The formation method includes but is not limited to PECVD, ALCVD, and the like.

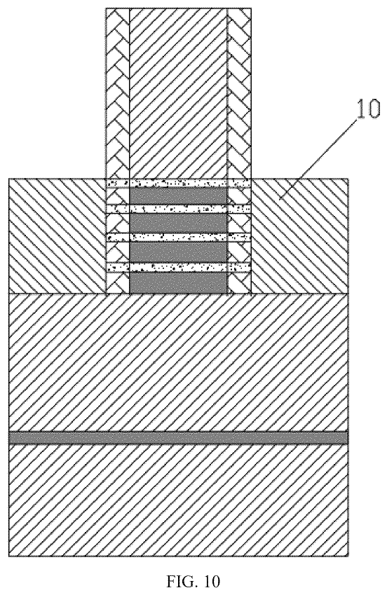

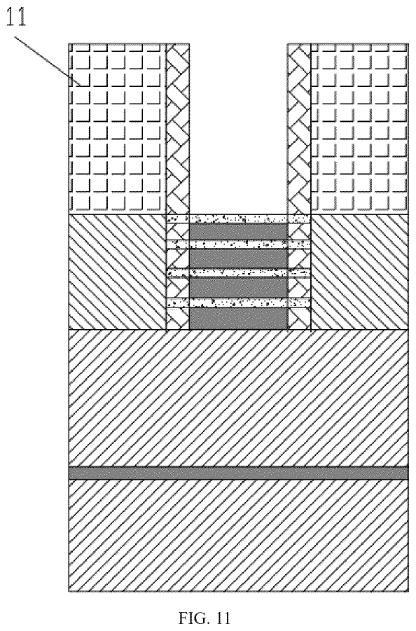

In Step S9, a doped semiconductor material is deposited in the source/drain area to form a source/drain region 10, as shown in FIG. 10 (a cross-sectional view in the Y-Y′ direction). In this step, the doping type is determined according to the transistor type. The semiconductor material may be silicon, silicon germanium, and the like.

In Step S10, a second dielectric layer 11 is formed on the source/drain region 10, and is flush with the dummy gate 7.

In Step S11, the dummy gate 7 is removed, as shown in FIG. 11 (a cross-sectional view in the Y-Y′ direction).

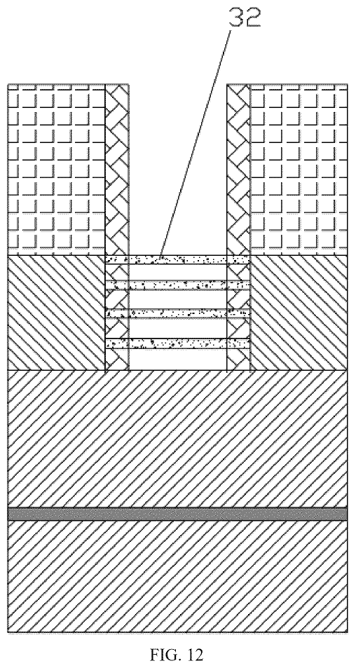

In Step S12, a part of the semiconductor materials in the superlattice stack is etched off to release a nanosheet channel. A stack formed by the nanosheets constitutes a plurality of conductive channels, as shown in FIG. 12 (a cross-sectional view in the Y-Y′ direction). For example, the silicon layer may be removed and the remaining silicon germanium layer 32 may be used as the nanosheet.

In Step S13, a gate-all-around is formed to surround the stack formed by the nanosheets. This step is usually performed in two steps, including the following Step S1301 and Step S1302.

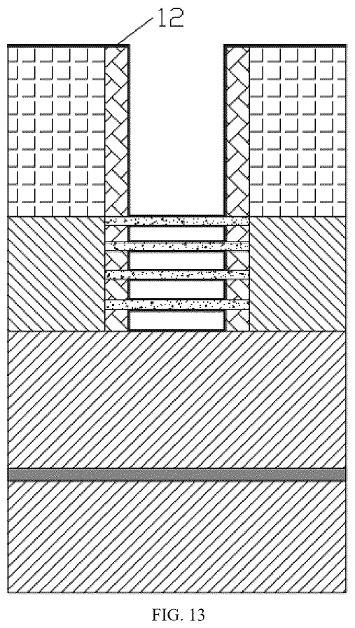

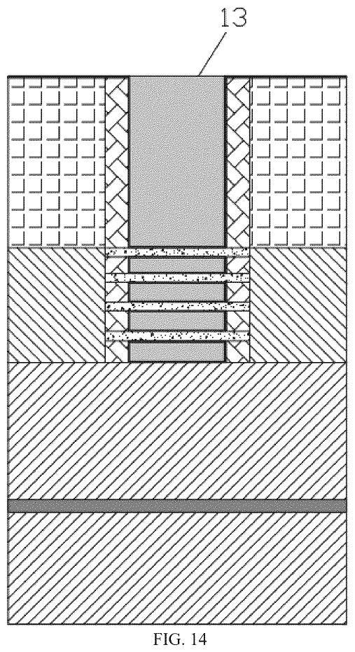

In Step S1301, a gate dielectric layer 12 is deposited first, which may be made of a HK material, as shown in FIG. 13 (a cross-sectional view in the Y-Y′ direction).

In Step S1302, a metal gate layer 13 is then deposited, as shown in FIG. 14 (a cross-sectional view in the Y-Y′ direction).

The above-mentioned Step S1 to Step S13 are all performed from the front side of the support substrate to obtain the basic structure of GAA. Then, the support substrate is flipped, and the subsequent steps are performed from the back side of the support substrate.

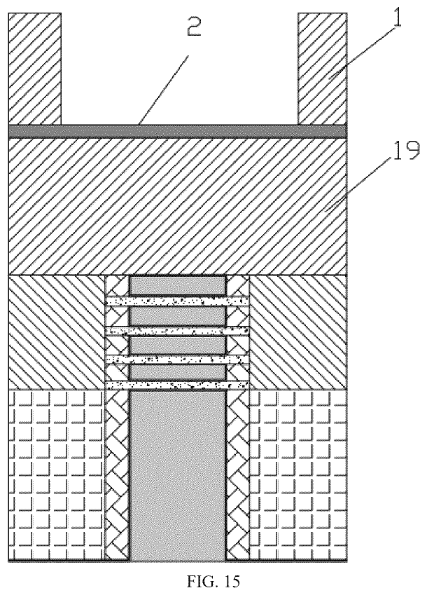

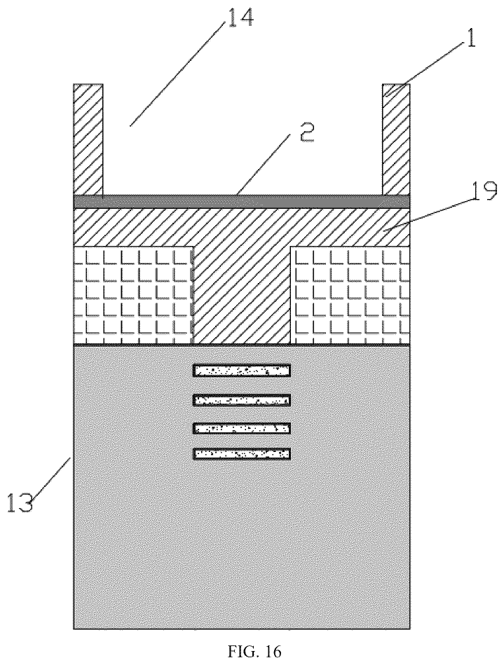

In Step S14, a first cavity structure 14 is formed by etching the support substrate 1 from the bottom and stopping the etching at the sacrificial layer 2, as shown in FIGS. 15 and 16 (FIG. 15 shows a cross-sectional view in the Y-Y′ direction, and FIG. 16 shows a cross-sectional view in the X-X′ direction). During the specific operation, the support substrate may be rotated by 180°, the substrate may be etched by using a photoresist as a mask layer, and then the mask layer may be removed.

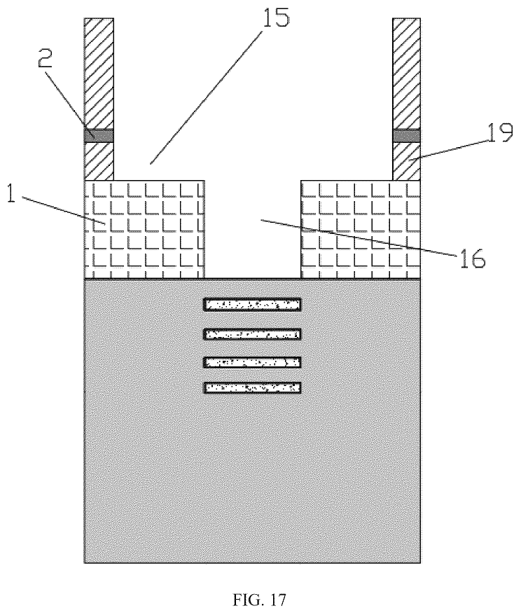

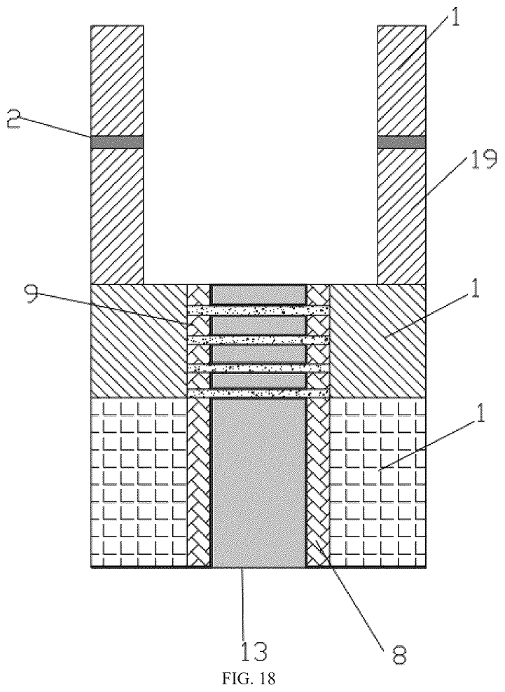

In Step S15, the sacrificial layer 2 and the first semiconductor layer 19 are selectively etched from the first cavity structure 14, and the etching is stopped at the formed gate-all-around, so as to form an array composed of the second cavity structure 15 and the gap unit 16 inside the first semiconductor layer, as shown in FIGS. 17 and 18 (FIG. 17 shows a cross-sectional view in the X-X′ direction, and FIG. 18 shows a cross-sectional view in the Y-Y′ direction). The sacrificial layer 2 and the first semiconductor layer 19 may be etched separately by using different methods or materials.

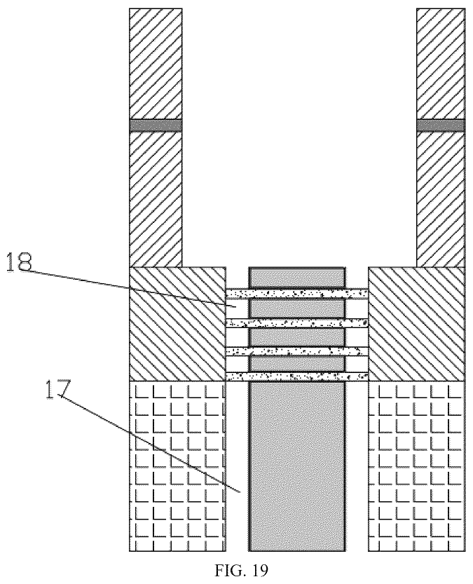

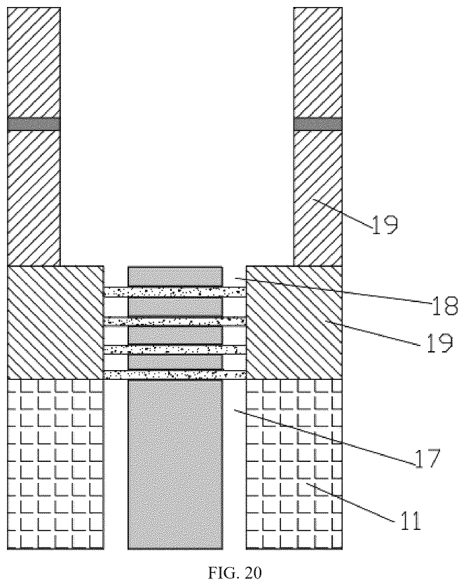

In Step S16, the first spacer and the second spacer are etched and removed to form a first empty spacer 17 and a second empty spacer 18, respectively, as shown in FIG. 19 (a cross-sectional view in the Y-Y′ direction). The first empty spacer 17 is located between the second dielectric layer 11 and the peripheral gate, and the second empty spacer 18 is located between the interlayer gate and the source/drain region. Etching may be performed using dry etching or wet etching. For example, if the first spacer and the second spacer are made of silicon nitride, wet etching may be performed using a hot phosphoric acid solution to remove the first spacer and the second spacer.

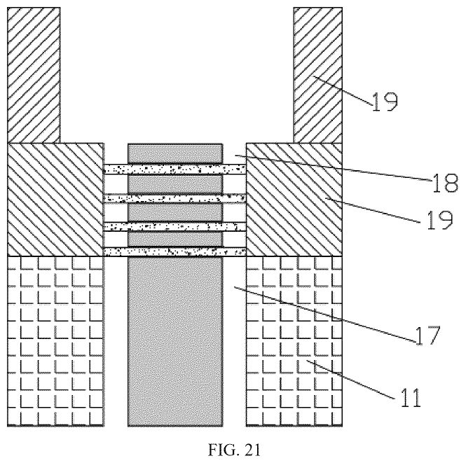

After Step S16, Step S17 may be optionally performed: the gate dielectric layer adjacent to the array composed of the gap unit is removed, and the gate dielectric layer on the sidewall of the first empty spacer 17 and the sidewall of the second empty spacer 18 is removed, which may further reduce the parasitic capacitance, as shown in FIG. 20 (a cross-sectional view in the Y-Y′ direction). The cross-sectional views after turning the device over are shown in FIGS. 22 and 23 (FIG. 22 shows a cross-sectional view in the Y-Y′ direction, and FIG. 23 shows a cross-sectional view in the X-X′ direction).

After Step S16, Step S18 may be optionally performed: the support substrate 1 and the remaining sacrificial layer 2 may be further removed, and a surface planarization process may be performed, as shown in FIG. 21 (a cross-sectional view in the Y-Y′ direction). If Step S18 is not performed, the stack structure composed of the support substrate 1, the remaining sacrificial layer 2, and the first semiconductor layer 19 functions as an overall “substrate”, and the first cavity structure 14 is generally conformal with the second cavity structure 15.

After Step S16, Step S19 may be optionally performed: the gas in the first empty spacer 17, the second empty spacer 18, the second cavity structure 15, and the gap unit 16 may be replaced with at least one of a reducing gas or an inert gas. If the gas is not replaced, the first empty spacer 17, the second empty spacer 18, the second cavity structure 15, and the gap unit 16 are naturally filled with the air. In order to improve the quality, the naturally filled air may be replaced with fresh air.

The sequence of Step S17, Step S18, and Step S19 may be changed arbitrarily.

In the above-mentioned process, a complete GAA structure is obtained from the front side, and a corrosion path of the air spacer and the air spacer are etched from the back side. Therefore, the obtained air spacer of the device has excellent shape retention and a more regular shape, so that a defect rate of the device is low.

Compared with the related art, the present disclosure achieves the following technical effects:
(1) The cavity and the gap array are provided on the substrate, the empty spacer is provided between the source/drain region and the gate-all-around, and the gas medium such as air is used as the isolation material at the above positions, so that the parasitic capacitance of the device may be greatly reduced, and the operating speed of the device and the circuit may be effectively improved.
(2) The gate dielectric is only provided between the metal gate layer and the nanosheet, and the gate dielectric is not provided on the sidewall of the empty spacer, so that the parasitic capacitance may be further reduced.
(3) The spacer etching pathway may be constructed by adding the sacrificial layer and the first semiconductor layer steps in the traditional preparation process of Nanosheet-GAAFET, and forming the fin by synchronously and conformally forming the first semiconductor layer and the superlattice stack. That is, after forming the gate-all-around, the support substrate, the sacrificial layer, the first semiconductor layer, and the spacer may be sequentially etched from the back side, so as to achieve an all-air spacer structure. The preparation process is stable and the air spacer has excellent shape retention.

The embodiments of the present disclosure are described above. However, these embodiments are only for the purpose of illustration, and are not intended to limit the scope of the present disclosure. The scope of the present disclosure is defined by the appended claims and the equivalents thereof. Without departing from the scope of the present disclosure, various substitutions and modifications may be made by those skilled in the art, and these substitutions and modifications should all fall within the scope of the present disclosure.

What is claimed is:

1. A stacked nanosheet gate-all-around device with an air spacer, comprising:
a substrate, wherein a first dielectric layer is provided on the substrate, a gap array is provided in the first dielectric layer, the gap array comprises a plurality of gap units, and each gap unit is in a fin shape above the substrate;
a nanosheet stacking portion provided above the gap unit, wherein the nanosheet stacking portion comprises a stack formed by a plurality of nanosheets, and the stack formed by the nanosheets constitutes a plurality of conductive channels;
a gate-all-around surrounding the nanosheet stacking portion; and
a source/drain region located on two opposite sides of the nanosheet stacking portion, wherein an empty spacer is provided between the source/drain region and the gate-all-around,
wherein an interior of the gap array and an interior of the empty spacer are filled with at least one of air, a reducing gas, or an inert gas.

2. The stacked nanosheet gate-all-around device with the air spacer according to claim 1, further comprising:
a second dielectric layer covering the gate-all-around,
wherein the gate-all-around comprises an interlayer gate filled among the plurality of nanosheets and a peripheral gate surrounding the nanosheet stacking portion, and
wherein the empty spacer comprises a first empty spacer located between the second dielectric layer and the peripheral gate, and a second empty spacer located between the interlayer gate and the source/drain region.

3. The stacked nanosheet gate-all-around device with the air spacer according to claim 1, wherein the substrate further has a cavity structure located below the gap unit.

4. The stacked nanosheet gate-all-around device with the air spacer according to claim 1, wherein a width of the nanosheet is in a range of 5 nm to 50 nm, and a thickness of the nanosheet is in a range of 3 nm to 20 nm.

5. The stacked nanosheet gate-all-around device with the air spacer according to claim 3, wherein a width of the cavity structure is in a range of 100 nm to 10 μm.

6. The stacked nanosheet gate-all-around device with the air spacer according to claim 1, wherein the gate-all-around comprises a gate dielectric layer and a metal gate layer, and the gate dielectric layer is located between the metal gate layer and the nanosheet.

7. A method of manufacturing a stacked nanosheet gate-all-around device with an air spacer, comprising:
providing a support substrate;
forming a sacrificial layer on the support substrate;
forming a first semiconductor layer on an upper surface of the sacrificial layer;
epitaxially growing a superlattice stack on a surface of the first semiconductor layer, wherein the superlattice stack is composed of different semiconductor materials alternatively stacked;
etching the superlattice stack and a partial thickness of the first semiconductor layer to form a fin;
forming a first dielectric layer on the first semiconductor layer as a shallow trench isolation, wherein an upper surface of the first dielectric layer is not higher than a bottom of the superlattice stack;
depositing a dummy gate on the fin and forming a first spacer on a sidewall of the dummy gate;
etching the superlattice stack in the fin to release a source/drain area;
forming a second spacer on a sidewall of the superlattice stack in the fin;
depositing a doped semiconductor material in the source/drain area to form a source/drain region;
forming a second dielectric layer on the source/drain region, wherein the second dielectric layer is flush with the dummy gate;
removing the dummy gate;
etching off a part of the semiconductor materials in the superlattice stack to release a nanosheet channel, wherein a stack formed by the nanosheets constitutes a plurality of conductive channels;
forming a gate-all-around to surround the stack formed by the nanosheets;
etching the support substrate from a bottom of the support substrate and stopping the etching at the sacrificial layer, so as to form a first cavity structure;
selectively etching the sacrificial layer and the first semiconductor layer from the first cavity structure, and stopping the selectively etching at the formed gate-all-around, so as to form a second cavity structure and a gap array inside the first semiconductor layer; and
etching and removing the first spacer and the second spacer to form a first empty spacer and a second empty spacer, respectively.

8. The method according to claim 7, wherein the forming a gate-all-around comprises: forming a gate dielectric layer, and then forming a metal gate layer by stacking,
wherein after etching and removing the first spacer and the second spacer, the method further comprises: removing the gate dielectric layer adjacent to the gap array, and removing the gate dielectric layer on a sidewall of the first empty spacer and a sidewall of the second empty spacer,
wherein after etching and removing the first spacer and the second spacer, the method further comprises: removing the remaining sacrificial layer and the support substrate, and
wherein the method further comprises: replacing a gas in the first empty spacer, the second empty spacer, the second cavity structure, and the gap array with at least one of air, a reducing gas, or an inert gas.

9. The method according to claim 7, wherein the first semiconductor layer is made of silicon, and the sacrificial layer is made of silicon germanium.

10. The method according to claim 7, wherein the first spacer and the second spacer are made of silicon nitride, and the first spacer and the second spacer are etched by using a phosphoric acid solution.
